(19) United States
(12) Patent Application Publication
(10) Pub. No.: US 2026/0198310 A1
(43) Pub. Date: Jul. 9, 2026

(54) SEMICONDUCTOR PACKAGE AND MANUFACTURING THE SAME

(71) Applicant: SAMSUNG ELECTRONICS CO., LTD., Suwon-si (KR)

(72) Inventors: Geongu JI, Suwon-si (KR); Myungsung Kang, Suwon-si (KR)

(73) Assignee: SAMSUNG ELECTRONICS CO., LTD., Suwon-si (KR)

(21) Appl. No.: 19/282,665

(22) Filed: Jul. 28, 2025

(30) Foreign Application Priority Data
Jan. 9, 2025 (KR) 10-2025-0003321

(51) Int. Cl. H01L 23/367; H01L 21/48; H01L 21/56; H01L 23/00; H01L 23/24; H01L 23/31; H01L 23/373; H01L 23/538; H01L 25/16; H10B 80/00; H10D 80/30

(52) U.S. Cl. CPC H10W 40/228; H10W 40/259; H10W 74/141; H10W 76/47; H10B 80/00; H10D 80/30; H10W 70/023; H10W 70/611; H10W 70/65; H10W 74/01; H10W 74/15; H10W 90/00; H10W 90/401; H10W 90/724; H10W 90/734

(57) ABSTRACT

A semiconductor package includes a semiconductor chip electrically connected to a package substrate through an interposer substrate interposed therebetween; a heat transfer material layer on the semiconductor chip; an encapsulant surrounding the semiconductor chip and the heat transfer material layer; a stiffener on the package substrate and spaced apart from the interposer substrate; and a heat dissipation plate on upper ends of the stiffener, the encapsulant, and the heat transfer material layer. The heat dissipation plate includes a plate portion located higher than the upper end of the encapsulant, and a protrusion portion protruding from a lower surface of the plate portion, which is in contact with the upper end of the stiffener, the heat transfer material layer is in contact with the semiconductor chip and protrusion portion of the heat dissipation plate, and a portion of a side surface of the protrusion portion is spaced apart from the encapsulant.

### CROSS-REFERENCE TO RELATED APPLICATION(S)

This application claims benefit of priority to Korean Patent Application No. 10-2025-0003321 filed on Jan. 9, 2025 in the Korean Intellectual Property Office, the disclosure of which is incorporated herein by reference in its entirety.

### BACKGROUND

The present inventive concept relates to a semiconductor package and a method for manufacturing the semiconductor package.

As electronic devices become lighter and higher performance, the development of miniaturized and high-performance semiconductor chips is required. In order to improve the reliability of high-performance semiconductor chips, the importance of heat dissipation characteristics of semiconductor packages is increasing.

### SUMMARY

An aspect of the present inventive concept is to provide a semiconductor package having improved reliability by improving heat dissipation characteristics of the semiconductor package, and a method for manufacturing the same.

According to an aspect of the present inventive concept, a semiconductor package includes a package substrate; an interposer substrate disposed on the package substrate; a semiconductor chip disposed on the interposer substrate and electrically connected to the package substrate; a heat transfer material layer disposed on the semiconductor chip; an encapsulant surrounding at least a portion of the semiconductor chip and at least a portion of the heat transfer material layer on the interposer substrate; a stiffener disposed on the package substrate and spaced apart from the interposer substrate; and a heat dissipation plate disposed on an upper end of the stiffener, an upper end of the encapsulant, and an upper end of the heat transfer material layer, wherein the heat dissipation plate includes a plate portion located on a level higher than the upper end of the encapsulant, and a protrusion portion protruding from a lower surface of the plate portion toward the semiconductor chip, the lower surface of the plate portion of the heat dissipation plate is in contact with the upper end of the stiffener, the heat transfer material layer is in contact with an upper surface of the semiconductor chip and a lower surface of the protrusion portion of the heat dissipation plate, and at least a portion of a side surface of the protrusion portion of the heat dissipation plate is spaced apart from the encapsulant.

According to an aspect of the present inventive concept, a semiconductor package includes an interposer substrate; a semiconductor chip disposed on the interposer substrate; a heat transfer material layer covering at least a portion of an upper surface of the semiconductor chip; an encapsulant surrounding a side surface of the semiconductor chip and a side surface of the heat transfer material layer on the interposer substrate; a heat dissipation plate disposed on the encapsulant and including a protrusion portion protruding toward the semiconductor chip; and an air gap disposed between a side surface of the protrusion portion and the encapsulant.

According to an aspect of the present inventive concept, a semiconductor package includes a package substrate; an interposer substrate disposed on the package substrate; a stiffener disposed on the package substrate and located more adjacent to an edge of the upper surface of the package substrate than the interposer substrate; a plurality of semiconductor chips including a first semiconductor chip and a second semiconductor chip, disposed on the interposer substrate and spaced apart from each other in a horizontal direction perpendicular to a stacking direction of the package substrate and the interposer substrate; an encapsulant surrounding side surfaces of the plurality of semiconductor chips on the interposer substrate; a heat dissipation plate disposed on an upper surface of the encapsulant and an upper surface of the stiffener; and at least one heat transfer material layer disposed between the plurality of semiconductor chips and the heat dissipation plate, wherein an upper surface of the heat transfer material layer is located on a level lower than the upper surface of the encapsulant, a first portion which is a portion of the upper surface of the heat transfer material layer is in contact with the heat dissipation plate, and a second portion which is a remaining portion of the upper surface of the heat transfer material layer is spaced from the heat dissipation plate along the stacking direction, and the second portion surrounds at least a portion of the first portion.

### BRIEF DESCRIPTION OF DRAWINGS

The and other aspects, characteristics, and advantages of the present inventive concept will be more clearly understood from the following detailed description, taken in conjunction with the accompanying drawings, in which:

FIG. 1A is a schematic cross-sectional view illustrating a semiconductor package according to example embodiments.

FIG. 1B is a schematic plan view illustrating a semiconductor package according to example embodiments.

FIG. 1C is a schematic plan view illustrating a semiconductor package according to example embodiments.

FIG. 2 is a schematic plan view illustrating a semiconductor package according to example embodiments.

FIG. 3 is a schematic cross-sectional view illustrating a semiconductor package according to example embodiments.

FIG. 4A is a schematic cross-sectional view illustrating a semiconductor package according to example embodiments.

FIG. 4B is a schematic cross-sectional view illustrating a semiconductor package according to example embodiments.

FIGS. 5, 6, 7, 8, 9, and 10 are schematic cross-sectional views illustrating a semiconductor package according to example embodiments.

FIG. 11 is a schematic process flow diagram illustrating a method of manufacturing a semiconductor package according to example embodiments.

FIGS. 12A, 12B, 12C, 12D, 12E, 12F, 12G, 12H, 12I, 12J, 12K, 12L, 12M, and 12N are cross-sectional views illustrating a process sequence to illustrate a method of manufacturing a semiconductor package according to example embodiments.

FIGS. 13A, 13B, and 13C are enlarged plan views illustrating a process sequence to illustrate a method of manufacturing a semiconductor package according to example embodiments.

### DETAILED DESCRIPTION

Hereinafter, preferred embodiments will be described with reference to the attached drawings. Hereinafter, terms such as ‘on,’ ‘upper,’ ‘upper portion,’ ‘upper surface,’ ‘below,’ ‘lower,’ ‘lower portion,’ ‘lower surface,’ ‘side surface,’ or the like can be understood to refer to the drawings unless otherwise explained.

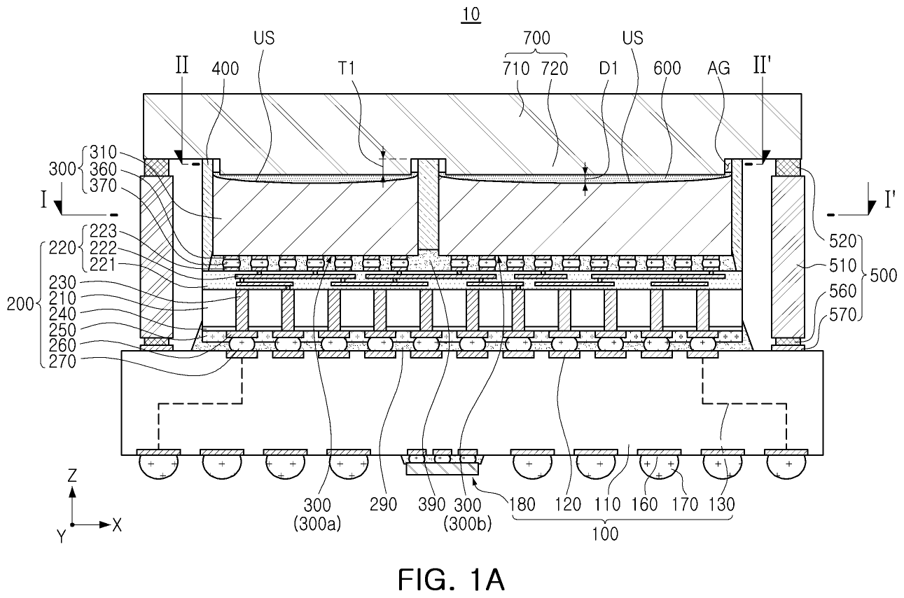

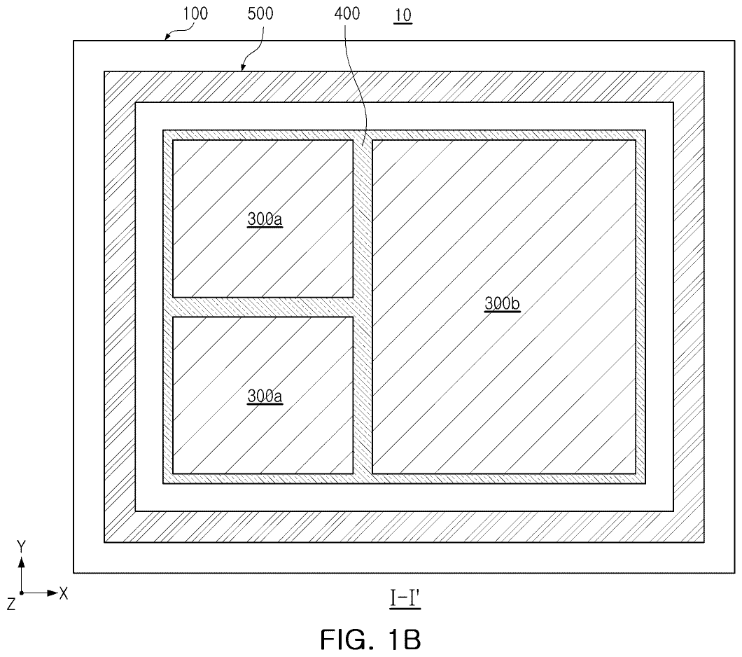

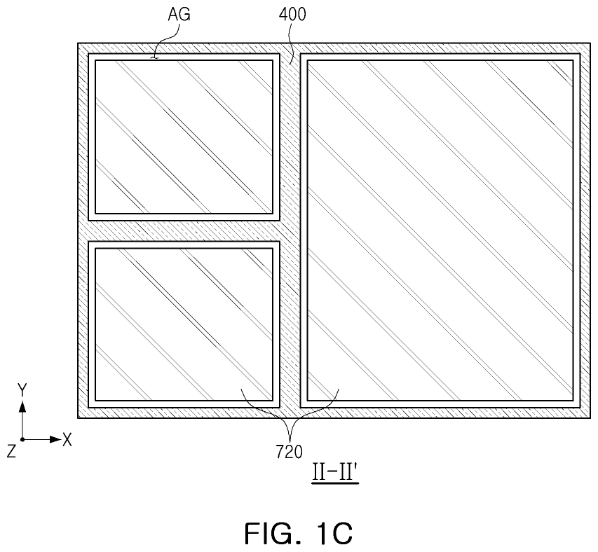

FIG. 1A is a schematic cross-sectional view illustrating a semiconductor package according to example embodiments.

FIG. 1B is a schematic plan view illustrating a semiconductor package according to example embodiments. FIG. 1B schematically illustrates a cross-section of the semiconductor package 10 of FIG. 1A, along line I-I′.

FIG. 1C is a schematic plan view illustrating a semiconductor package according to example embodiments. FIG. 1C schematically illustrates a cross-section of the semiconductor package 10 of FIG. 1A, along line II-II′.

Referring to FIGS. 1A to 1C, a semiconductor package 10 may include a package substrate 100, an interposer substrate 200, semiconductor chips 300, an encapsulant 400, a stiffener 500, a heat transfer material layer 600, and a heat dissipation plate 700. The semiconductor package 10 may further include an interposer underfill 290 and a semiconductor chip underfill 390.

The package substrate 100 may be a support substrate on which the interposer substrate 200 is mounted, and may be a substrate for a semiconductor package including a printed circuit board (PCB), a ceramic substrate, a glass substrate, a tape wiring substrate, or the like. For example, the package substrate 100 may be a one-sided printed circuit board (PCB), a double-sided printed circuit board (PCB), or a multi-layer printed circuit board (PCB). The package substrate 100 may include a package body 110, upper pads 120, an interconnection circuit 130, lower pads 160, external connection terminals 170, and a passive element 180.

The package body 110 may have an upper surface extending in an X-direction and a Y-direction, and may have a lower surface opposing the upper surface. The interposer substrate 200 may be mounted on the upper surface of the package body 110. The package body 110 may include a different material, depending on a type. The package body 110 may include an insulating material electrically and physically protecting the interconnection circuit 130, for example, a thermosetting resin such as an epoxy resin, a thermoplastic resin such as a polyimide, or a prepreg including an inorganic filler or/and a glass fiber (glass fiber, glass cloth, glass fabric), an Ajinomoto build-up film (ABF), a frame retardant 4(FR 4 ), or the like.

The upper pads 120, the lower pads 160, and the interconnection circuit 130 may form an electrical path connecting a lower surface and an upper surface of the package substrate 100. The interconnection circuit 130 may include at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or an alloy including two or more metals.

The external connection terminals 170 connected to the lower pads 160 may be disposed on the lower surface of the package body 110. The external connection terminals 170 may include, for example, a solder ball. The solder ball may include tin (Sn), bismuth (Bi), lead (Pb), silver (Ag), or an alloy thereof.

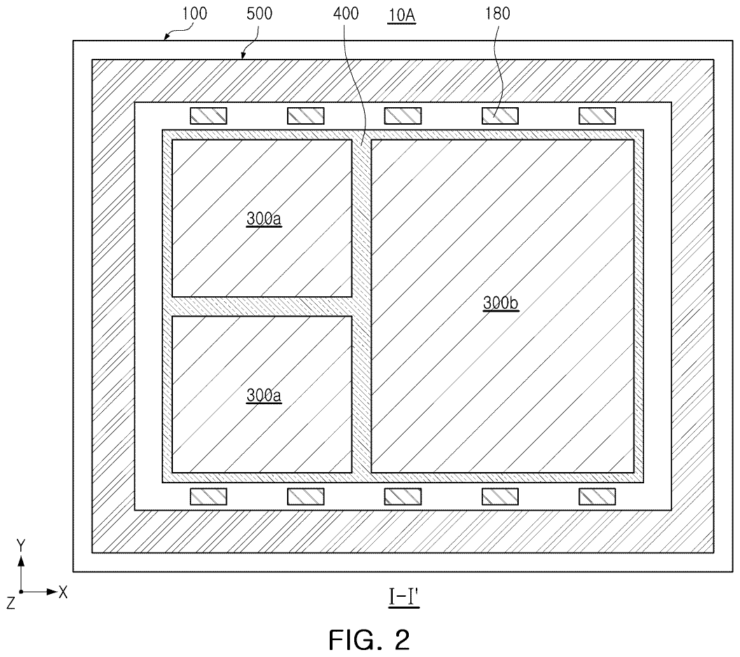

The passive element 180 may be disposed below the lower surface of the package body 110. The package substrate 100 may include at least one passive element 180, and the number of passive elements 180 may be greater than that illustrated. The passive element 180 may include, for example, a capacitor, an inductor, a bead, or the like. The passive element 180 may be flip-chip bonded to the lower surface of the package body 110. The passive element 180 may be electrically connected to the lower pads 160 and the interconnection circuit 130 through the solder bump, or the like. An underfill resin may be filled between the passive element 180 and the package body 110. A position at which the passive element 180 is disposed is not limited to that illustrated, and may also be disposed between the interposer substrate 200 and the stiffener 500 on the upper surface of the package body 110, as illustrated in FIG. 2.

The interposer substrate 200 may be disposed on the package substrate 100. The interposer substrate 200 may be a support substrate on which the semiconductor chips 300 is mounted, and may be disposed between the package substrate 100 and the semiconductor chips 300. The interposer substrate 200 may include a semiconductor substrate 210, a circuit layer 220, through-vias 230, a lower insulating layer 240, a lower protective layer 250, lower connection pads 260, and connection conductors 270.

The semiconductor substrate 210 may include a semiconductor element such as silicon or germanium, or a compound semiconductor such as silicon carbide (SiC), gallium arsenide (GaAs), indium arsenide (InAs), or indium phosphide (InP).

The circuit layer 220 may be disposed on the semiconductor substrate 210, and may include an interlayer insulating layer 221, a connection circuit 222 including a multilayer pattern layer and a contact via, and upper connection pads 223. The interlayer insulating layer 221 may include an insulating material. For example, the interlayer insulating layer 221 may include silicon oxide or silicon nitride. The connection circuit 222 may configure a host interface HIF interconnecting the semiconductor chips 300. The host interface HIF may use various standards, for example, a parallel advanced technology attachment (PATA) standard, a serial advanced technology attachment (SATA) standard, an SCSI standard, a PCI express (PCIe) standard, a universal frame system (UFS) standard, a universal serial bus (USB) standard, or a Thunderbolt standard. The SATA standard may encompass not only SATA-1, but also all SATA series standards such as SATA-2, SATA-3, and external SATA (e-SATA). The PCIe standard may encompass not only PCIe 1.0, but also all PCIe series standards such as PCIe 2.0, PCIe 2.1, PCIe 3.0, PCIe 4.0, or the like. The SCSI standard may encompass all SCSI series standards such as parallel SCSI, serial combined SA-SCSI (SAS), iSCSI, or the like. The upper connection pads 223 may be disposed on the interlayer insulating layer 221, and may be in contact with and connected to the connection circuit 222. The upper connection pads 223 may be electrically connected to the through-vias 230 through the connection circuit 222, and may be electrically connected to the lower connection pads 260 through the through-vias 230. The upper connection pads 223 may include more or fewer connection pads than those illustrated. The connection circuit 222 and the upper connection pads 223 may include, for example, but are not limited to, at least one metal material of aluminum (Al), copper (Cu), nickel (Ni), tungsten (W), platinum (Pt), or gold (Au).

The through-vias 230 may be through silicon vias (TSV) penetrating the semiconductor substrate 210 in a vertical direction (e.g., Z-direction). Here, the vertical direction may refer to a stacking direction in which the package substrate 100, the interposer substrate 200, and the semiconductor chips 300 are stacked on one another. The through-vias 230 may penetrate the lower insulating layer 240. The through-vias 230 may provide an electrical path connecting the lower connection pads 260 and the upper connection pads 223. The through-via 230 may include a conductive plug and a barrier film surrounding the conductive plug. The conductive plug may include a metal material, for example, tungsten (W), titanium (Ti), aluminum (Al), or copper (Cu). The conductive plug may be formed by a plating process, a PVD process, or a CVD process. The barrier film may include an insulating barrier film and/or a conductive barrier film. The insulating barrier film may be formed of an oxide, a nitride, a carbide, a polymer, or a combination thereof. The conductive barrier film may include, for example, a metal compound such as tungsten nitride (WN), titanium nitride (TiN), or tantalum nitride (TaN). The barrier film may be formed by a PVD process, or a CVD process.

The lower insulating layer 240 may be disposed below the semiconductor substrate 210, and may physically and electrically separate the lower connection pads 260 from the semiconductor substrate 210. The lower insulating layer 240 may include an insulating material. For example, the lower insulating layer 240 may include silicon oxide (SiO), silicon nitride (SiN), silicon carbide (SiC), silicon oxynitride (SiON), or silicon carbonitride (SiCN).

The lower protective layer 250 may be disposed below the lower insulating layer 240, and may cover a portion of each of the lower connection pads 260. The lower protective layer 250 may expose at least a portion of a lower surface of each of the lower connection pads 260. The lower protective layer 250 may include an insulating material. For example, the lower protective layer 250 may include a prepreg, an ABF, FR-4, BT, or a photo solder resist (PSR).

The lower connection pads 260 may be disposed below the semiconductor substrate 210, and may be in contact with and connected to the through-vias 230. The lower connection pads 260 may be electrically connected to the connection circuit 222 through the through-vias 230, and may be electrically connected to the upper connection pads 223 through the connection circuit 222. The lower connection pads 260 may include more or fewer than those illustrated. The lower connection pads 260 may include, for example, but are not limited to, at least one metal material selected from the group consisting of aluminum (Al), copper (Cu), nickel (Ni), tungsten (W), platinum (Pt), or gold (Au).

The connection conductors 270 may be disposed below the lower connection pads 260. The connection conductors 270 may be electrically connected to the semiconductor chips 300 through the lower connection pads 260, the through-vias 230, the connection circuit 222, and the upper connection pads 223. The connection conductors 270 may have a spherical shape or an elliptical shape formed of a low-melting-point metal, such as tin (Sn), indium (In), bismuth (Bi), antimony (Sb), copper (Cu), silver (Ag), zinc (Zn), lead (Pb), or an alloy including these (e.g., Sn—Ag—Cu).

The interposer underfill 290 may surround the connection conductors 270. The interposer underfill 290 may fill a space between a lower portion of the interposer substrate 200 and an upper portion of the package substrate 100. The interposer underfill 290 may include an insulating resin such as an epoxy resin, and may physically and electrically protect the connection conductors 270.

The semiconductor chips 300 may be mounted on the interposer substrate 200, and may be electrically connected to the package substrate 100 through the interposer substrate 200. The semiconductor chips 300 may be mounted on the interposer substrate 200 in a flip-chip manner. The semiconductor chips 300 may include an integrated circuit area, and the integrated circuit area may include a logic circuit such as a central processor (CPU), a graphic processor (GPU), a field programmable gate array (FPGA), an application processor (AP), a digital signal processor, an encryption processor, a microprocessor, a microcontroller, an analog-to-digital converter, an application-specific IC (ASIC), or the like, or a memory circuit such as a volatile memory such as a dynamic RAM (DRAM), a static RAM (SRAM), or the like, and a non-volatile memory such as a phase change RAM (PRAM), a magnetic RAM (MRAM), a resistive RAM (RRAM), a flash memory, or the like. The semiconductor chips 300 may include a plurality of semiconductor chips 300 disposed on the interposer substrate 200. For example, the semiconductor chips 300 may include a first semiconductor chip 300a and a second semiconductor chip 300b, disposed side by side on the interposer substrate 200. The first semiconductor chip 300a and the second semiconductor chip 300b may include different types of semiconductor chips. For example, in an embodiment, the first semiconductor chip 300a may include a memory chip, and the second semiconductor chip 300b may include a logic chip. For example, the first semiconductor chip 300a may be provided as a high-capacity memory device such as a high bandwidth memory (HBM), and the second semiconductor chip 300b may be provided as an application-specific integrated circuit (ASIC) chip. The number of semiconductor chips 300 may be disposed in a greater or lesser number than those illustrated in the drawings. In an embodiment, the first semiconductor chip 300a, which may be a memory chip, may be disposed in a greater number than the second semiconductor chip 300b, which may be a logic chip. For example, the first semiconductor chip 300a may be disposed in a multiple of the number of the second semiconductor chip 300b. Each of the semiconductor chips 300 may include a chip body 310, chip pads 360, and chip bumps 370.

The chip body 310 may include an integrated circuit area including a memory circuit or a logic circuit. The chip body 310 may have a front surface on which the chip pads 360 may be disposed and a rear surface opposite the front surface. The front surface of the chip body 310 may be referred to as a lower surface, and the rear surface of the chip body 310 may be referred to as an upper surface. The upper surface of the chip body 310 may be referred to as an upper surface of the semiconductor chip 300. The upper surface of the chip body 310 may be located on a level lower than an upper surface of the encapsulant 400. An upper end of the chip body 310 may be located on a level lower than an upper end of the encapsulant 400. The term “upper end” refers to a portion that may be located at the highest level in the vertical direction (for example, Z-direction) based on the upper surface of the package substrate 100 in a certain configuration. Conversely, the term “lower end” refers to a portion that may be located at the lowest level in the vertical direction in a certain configuration. In an embodiment, the upper surface of the chip body 310 may be a concavely recessed upper surface. Since the upper surface of the chip body 310 may be located on a lower level than the upper surface of the encapsulant 400, the heat transfer material layer 600 on the upper surface of the chip body 310 may also be located on a lower level than the upper surface of the encapsulant 400, and the heat transfer material layer 600 may be prevented from escaping outside the encapsulant 400 during a manufacturing process. In addition, a thickness of the heat transfer material layer 600 may be controlled to a desired thickness, and a semiconductor package having improved reliability may be provided. Features related thereto have been described in detail in the description of the manufacturing method. The semiconductor chips 300 may have a recessed upper surface US, and the recessed upper surface US may be a concave upper surface. Upper ends of the semiconductor chips 300 may be in contact with an inner side surface of the encapsulant 400.

The chip pads 360 may be disposed below the chip body 310. The chip pads 360 may be electrically connected to the upper connection pads 223 through the chip bumps 370. The chip pads 360 may include more or less than the number illustrated. The chip pads 360 may include, for example, but are not limited to, at least one metal material among aluminum (Al), copper (Cu), nickel (Ni), tungsten (W), platinum (Pt), or gold (Au).

The chip bumps 370 may be disposed below the chip pads 360. The chip bumps 370 may be electrically connected to the connection circuit 222 through the upper connection pads 223. The chip bumps 370 may have a spherical shape or an elliptical shape formed of a low-melting point metal such as tin (Sn), indium (In), bismuth (Bi), antimony (Sb), copper (Cu), silver (Ag), zinc (Zn), lead (Pb), or an alloy containing these (e.g., Sn—Ag—Cu).

The semiconductor chip underfill 390 may surround the chip bumps 370. The semiconductor chip underfill 390 may fill a space between a lower portion of the semiconductor chip 300 and an upper portion of the interposer substrate 200. The semiconductor chip underfill 390 may include an insulating resin such as an epoxy resin, and may physically and electrically protect the chip bumps 370. The semiconductor chip underfill 390 may have a capillary underfill (CUF) structure, but may not be limited thereto. As described below, the semiconductor chip underfill 390 may have a molded underfill (MUF) structure integrated with the encapsulant 400.

The encapsulant 400 may surround the semiconductor chips 300 on the interposer substrate 200. The encapsulant 400 may encapsulate at least a portion of the semiconductor chips 300. The upper surface of the encapsulant 400 may be located on a level higher than upper surfaces of the semiconductor chips 300. The upper end of the encapsulant 400 may be located on a level higher than upper ends of the semiconductor chips 300. An outer side surface of the encapsulant 400 may be coplanar with an outer side surface of the interposer substrate 200. The encapsulant 400 may include an inner side surface forming a portion of an outer wall of the air gap AG on the semiconductor chips 300. The inner surface of the encapsulant 400 may face a side surface of a protrusion portion 720 of the heat dissipation plate 700. The encapsulant 400 may cover a side surface of the semiconductor chips 300, and may expose the upper surface of the semiconductor chips 300. For example, the encapsulant 400 may not cover the upper surface of the semiconductor chips 300. Since the upper surface of the encapsulant 400 surrounding the side surfaces of the semiconductor chips 300 may be located on a higher level than the upper surfaces of the semiconductor chips 300, the upper surfaces of the semiconductor chips 300 may have a trench structure recessed in an inner side of the upper surface of the encapsulant 400.

The stiffener 500 may be disposed on the package substrate 100. The stiffener 500 may be spaced apart from the interposer substrate 200 and the encapsulant 400 on the package substrate 100. The stiffener 500 may have a ring shape surrounding the outer side surface of the interposer substrate 200 and the outer side surface of the encapsulant 400 on the package substrate 100. The stiffener 500 may serve as a support for the heat dissipation plate 700 and, together with the heat dissipation plate 700, may protect the semiconductor chips 300 from external electromagnetic interference. An upper surface of the stiffener 500 may be located at the same level as the upper surface of the encapsulant 400. The upper surface of the stiffener 500 may be in contact with a lower surface of a plate portion 710 of the heat dissipation plate 700. The stiffener 500 may include a support structure 510, an upper bonding layer 520, a lower bonding layer 560, and a support pad 570.

The support structure 510 may be an element forming a main body of the stiffener 500, and may include a conductive material. The support structure 510 may have a ring shape surrounding the outer side surface of the interposer substrate 200 and the outer side surface of the encapsulant 400. For example, the support structure 510 may include at least one of aluminum (Al), nickel (Ni), gold (Au), silver (Ag), copper (Cu), or iron (Fe). In an embodiment, the support structure 510 may include the same material as the heat dissipation plate 700.

The upper bonding layer 520 and the lower bonding layer 560 may be disposed on upper and lower surfaces of the support structure 510, respectively. The upper bonding layer 520 may be in contact with the lower surface of the plate portion 710 of the heat dissipation plate 700 on the upper surface of the support structure 510, and may fix the heat dissipation plate 700 on the support structure 510. The lower bonding layer 560 may be in contact with the lower surface of the support structure 510 on the support pad 570, and may fix the support structure 510 on the support pad 570. An upper surface of the upper bonding layer 520 may be referred to as the upper surface of the stiffener 500. The upper bonding layer 520 and the lower bonding layer 560 may have a ring shape surrounding the outer side surface of the interposer substrate 200 and the outer side surface of the encapsulant 400, like the support structure 510. In an embodiment, the upper bonding layer 520 and the lower bonding layer 560 may have an opening discharging gas that may be generated during a process. The upper bonding layer 520 and the lower bonding layer 560 may include a material that bonds well with a conductive material. For example, the upper bonding layer 520 and the lower bonding layer 560 may include a polymer or an epoxy. In an embodiment, the upper bonding layer 520 and the lower bonding layer 560 may include silicon (Si) and aluminum oxide (AlₓO_{y}).

The support pad 570 may be disposed on the package substrate 100. The support pad 570 may be in contact with the upper surface of the package substrate 100 in a position in which the stiffener 500 is disposed. The lower surface of the support pad 570 may be referred to as the lower surface of the stiffener 500. The support pad 570 may include a conductive material. For example, the support pad 570 may include at least one of aluminum (Al), nickel (Ni), gold (Au), silver (Ag), copper (Cu), or iron (Fe).

The heat transfer material layer 600 may be disposed on the upper surface of the semiconductor chip 300. The heat transfer material layer 600 may be disposed between the semiconductor chip 300 and the heat dissipation plate 700. The heat transfer material layer 600 may have a curved lower surface formed as a result of the recessed upper surface US of the semiconductor chip 300 having a concave shape. A lower surface of the heat transfer material layer 600 may be located on a lower level than an upper end of the semiconductor chip 300. A thickness D1 of the heat transfer material layer 600 may change depending on a shape of the semiconductor chips 300, an amount of the heat transfer material layer 600, or the like, and the semiconductor package 10 may control the thickness D1 of the heat transfer material layer 600 by controlling a depth of the recessed upper surface US of the semiconductor chips 300. In an embodiment, the thickness D1 of the heat transfer material layer 600 may range from 10 μm to 1000 μm. The heat transfer material layer 600 may be in contact with the upper surface of the semiconductor chip 300 and the lower surface of the protrusion portion 720 of the heat dissipation plate 700. A first portion, which may be a portion of the upper surface of the heat transfer material layer 600, may be in contact with the lower surface of the protrusion portion 720, and a second portion, which may be a remaining portion of the upper surface of the heat transfer material layer 600, may be spaced apart from the lower surface of the plate portion 710 of the heat dissipation plate 700. The second portion may surround at least a portion of the first portion. At least a portion of the second portion may be located at the same level as or higher than the first portion. An upper portion of the heat transfer material layer 600 may be located in an area not overlapping the protrusion portion 720, and may be in contact with a side surface of the protrusion portion 720. A portion of the heat transfer material layer 600 not overlapping the protrusion portion 720 may constitute a portion of the outer wall of the air gap AG, for example, a lower wall of the air gap AG. The heat transfer material layer 600 may be in contact with an inner side surface of the encapsulant 400 constituting a portion of the outer wall of the air gap AG. In an embodiment, unlike that illustrated, the heat transfer material layer 600 may be disposed only in a portion overlapping the protrusion portion 720, and may not be in contact with the inner side surface of the encapsulant 400. The heat transfer material layer 600 may include a thermally conductive grease, a thermally conductive adhesive, a thermally conductive adhesive tape, or the like. Since the heat transfer material layer 600 is formed on a level lower than the upper surface of the encapsulant 400 on the recessed upper surface US, a phenomenon of the heat transfer material layer 600 being separated from the outer side surface of the encapsulant 400 during the manufacturing process may be prevented. Therefore, other elements that may be disposed on the upper surface of the package substrate 100 may be prevented from being contaminated, and the thickness D1 of the heat transfer material layer 600 may be appropriately controlled, thereby providing a semiconductor package having improved reliability.

As one exemplary measurement method of the aforementioned thicknesses, a “thickness” of an element having two opposing surfaces may mean an average value of shortest distances between the two targeted surfaces measured in a direction perpendicular to the targeted surfaces at multiple locations (e.g., 3, 5, or 10) at equal intervals (or non-equal intervals, alternatively). In one embodiment, a “thickness” of an element having a varying thickness may mean a vertical distance (e.g., a distance measured in the vertical direction or the Z-direction) between two targeted points of the respective opposing surfaces of the element. Other methods appreciated by one of ordinary skill in the art, even if not described in the present disclosure, may also be used.

The heat dissipation plate 700 may be disposed on the encapsulant 400, the stiffener 500, and the heat transfer material layer 600. The heat dissipation plate 700 may be in contact with the upper surface of the encapsulant 400, the upper surface of the stiffener 500, and the upper surface of the heat transfer material layer 600. The heat dissipation plate 700 may be in contact with an upper end of the encapsulant 400, an upper end of the stiffener 500, and an upper end of the heat transfer material layer 600. The heat dissipation plate 700 may include a material having excellent thermal conductivity, for example, aluminum (Al), gold (Au), silver (Ag), copper (Cu), iron (Fe), graphite, graphene, or the like. In an embodiment, the heat dissipation plate 700 may include the same material as the support structure 510 of the stiffener 500. The heat dissipation plate 700 may include a plate portion 710 and a protrusion portion 720 protruding from below the plate portion 710 toward the semiconductor chips 300. The plate portion 710 may be defined as a portion located on a level higher than the upper end of the encapsulant 400, and the protrusion portion 720 may be defined as a portion located on a level lower than the upper end of the encapsulant 400. The plate portion 710 may be in contact with the upper surface of the encapsulant 400 and the upper surface of the stiffener 500. The plate portion 710 may be in contact with the upper end of the encapsulant 400 and the upper end of the stiffener 500. A planar area of the plate portion 710 may be greater than a planar area of the interposer substrate 200. A portion of the lower surface of the plate portion 710 located closer to the inner side surface of the encapsulant 400 may constitute the outer wall of the air gap AG, particularly, an upper wall of the air gap AG. A lower surface of the heat dissipation plate 700 may have a step difference due to the protrusion portion 720. The step difference on the lower surface of the heat dissipation plate 700 may overlap the semiconductor chips 300. The protrusion portions 720 may be present in multiple numbers, and the protrusion portions 720 may be located on the upper surface of each of the semiconductor chips 300. The protrusion portions 720 may be disposed in the same number corresponding to the semiconductor chips 300. The protrusion portions 720 may overlap the semiconductor chips 300. A planar area of each of the protrusion portions 720 may be less than a planar area of the semiconductor chip 300 overlapping. A protrusion length T1 of the protrusion portion 720 may be greater than the thickness D1 of the heat transfer material layer 600. According to an embodiment, the protrusion length T1 of the protrusion portion 720 may be less than the thickness of the heat transfer material layer 600. In an embodiment, at least a portion of a side surface of the protrusion portion 720 of the protrusion portion may be spaced apart from the encapsulant 400. The side surface of the protrusion portion 720 may form the outer wall of the air gap AG, particularly an inner side wall of the air gap AG.

The air gap AG may be an empty space confined by the encapsulant 400, the heat transfer material layer 600, the lower surface of the plate portion 710 of the heat dissipation plate 700, and the side surface of the protrusion portion 720 of the heat dissipation plate 700. The air gap AG may be a space formed when the planar area of the protrusion portion 720 is formed smaller than the planar area of the semiconductor chip 300. The air gap AG may surround the side surface of the protrusion portion 720. As the protrusion portions 720 exist in multiple numbers, the air gaps AG may also exist in multiple numbers. In an embodiment, when the heat transfer material layer 600 is disposed only in an area overlapping the protrusion portion 720, the lower surface of the air gap AG may be formed by the recessed upper surface US of the semiconductor chip 300. For example, such an air gap structure may help improving the reliability of a semiconductor package by preventing the heat transfer material layer 600 from leaking out of the encapsulant 400.

In the description of the embodiments below, any description overlapping the description described above with reference to FIGS. 1A to 1C will be omitted.

FIG. 2 is a schematic plan view illustrating a semiconductor package according to example embodiments.

Referring to FIG. 2, in a semiconductor package 10A of FIG. 2, a passive element 180 may be disposed adjacent to a semiconductor chips 300 on an upper surface of a package substrate 100. The passive element 180 may be disposed not only on a lower surface of the package substrate 100 but also on the upper surface of the package substrate 100. The number of passive elements 180 disposed on the upper surface of the package substrate 100 may be greater or less than that illustrated, and may be disposed in a greater or less size than that illustrated. Since an upper surface of an encapsulant 400 may be located on a higher level than upper surfaces of the semiconductor chips 300, and a heat transfer material layer 600 may be formed on a lower level than the upper surface of the encapsulant 400, the heat transfer material layer 600 may be controlled not to escape from an outer side surface of the encapsulant 400, and a phenomenon of contaminating the passive elements 180 on the package substrate 100 by the heat transfer material layer 600 may be prevented. The stiffener 500 may extend further toward an outer side surface of the package substrate 100, and may be disposed with a greater thickness, as compared to the stiffener 500 of the semiconductor package 10 of FIGS. 1A to 1C. By controlling the thickness of the stiffener 500, warpage of the semiconductor package may be improved.

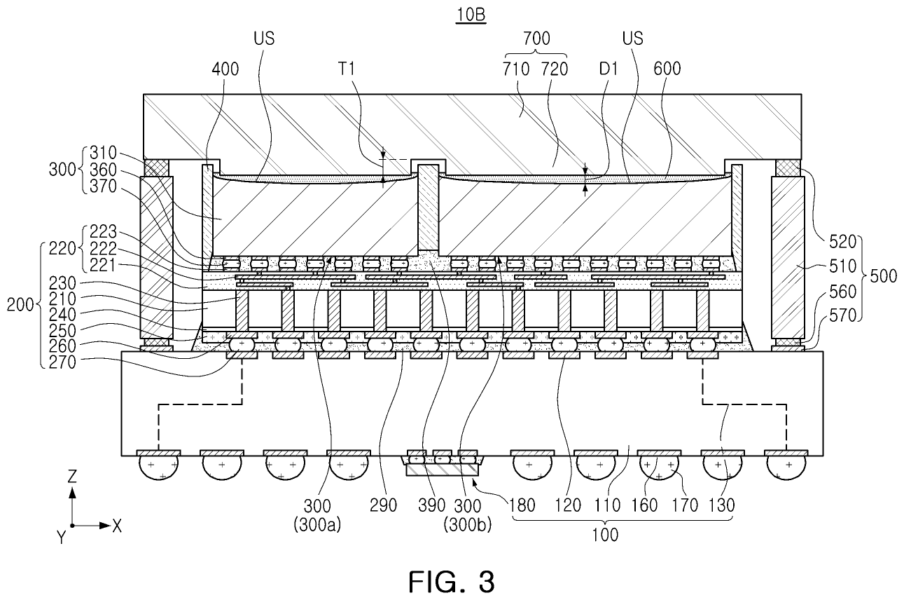

FIG. 3 is a schematic cross-sectional view illustrating a semiconductor package according to example embodiments.

Referring to FIG. 3, unlike the semiconductor package 10 of FIGS. 1A to 1C, an encapsulant 400 and a heat dissipation plate 700 included in a semiconductor package 10B may be spaced apart from each other. An upper surface of the encapsulant 400 may be located on a lower level than an upper surface of a stiffener 500. The upper surface of the encapsulant 400 may be located on a higher level than upper surfaces of semiconductor chips 300 and an upper surface of a heat transfer material layer 600. A lower surface of a plate portion 710 of a heat dissipation plate 700 may be in contact with the upper surface of the stiffener 500, and may be spaced apart from the upper surface of the encapsulant 400. As the heat dissipation plate 700 may be disposed to be spaced apart from the encapsulant 400, a gas on the semiconductor chips 300 that may occur during a process may be discharged, and a stress that the heat dissipation plate 700 applies to the semiconductor chips 300 may be relatively alleviated. As the encapsulant 400 and the heat dissipation plate 700 are spaced apart, the air gap AG of FIGS. 1A to 1C is not included. A characteristic that the encapsulant 400 and the heat dissipation plate 700 are spaced apart from each other may be applied not only to the present embodiment but also to other embodiments.

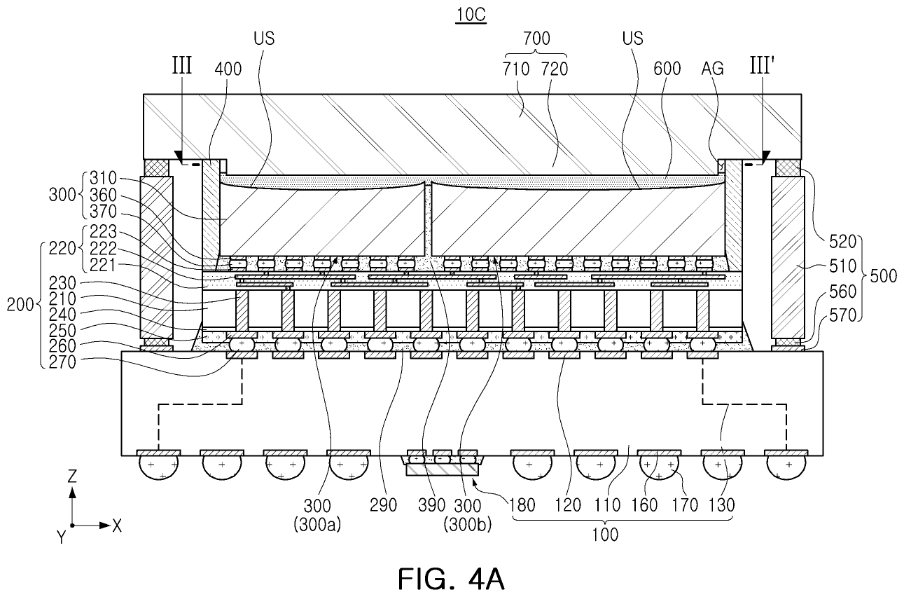

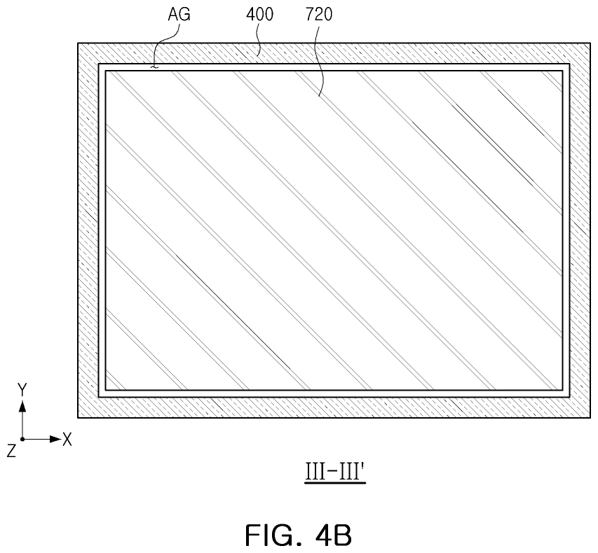

FIG. 4A is a schematic cross-sectional view illustrating a semiconductor package according to example embodiments.

FIG. 4B is a schematic cross-sectional view illustrating a semiconductor package according to example embodiments. FIG. 4B schematically illustrates a cross-section of the semiconductor package 10C of FIG. 4A, taken along line III-III′.

Referring to FIGS. 4A and 4B, unlike the semiconductor package 10 of FIGS. 1A to 1C, a semiconductor package 10C may include a heat dissipation plate 700 including a single protrusion portion 720. A gap between semiconductor chips 300 may be narrow enough that an encapsulant 400 does not penetrate, and a semiconductor chip underfill 390 may extend between the semiconductor chips 300 toward the heat dissipation plate 700. An upper end of the semiconductor chip underfill 390 may be located between the semiconductor chips 300, and may be in contact with a lower end of a heat transfer material layer 600 on a level lower than upper surfaces of the semiconductor chips 300. The upper end of the semiconductor chip underfill 390 may be located on a level closer to an upper surface of the encapsulant 400 than to a lower surface of the encapsulant 400. The heat transfer material layer 600 may include a portion extending between the semiconductor chips 300 toward an interposer substrate 200, and the lower end of the heat transfer material layer 600 may be located between the semiconductor chips 300.

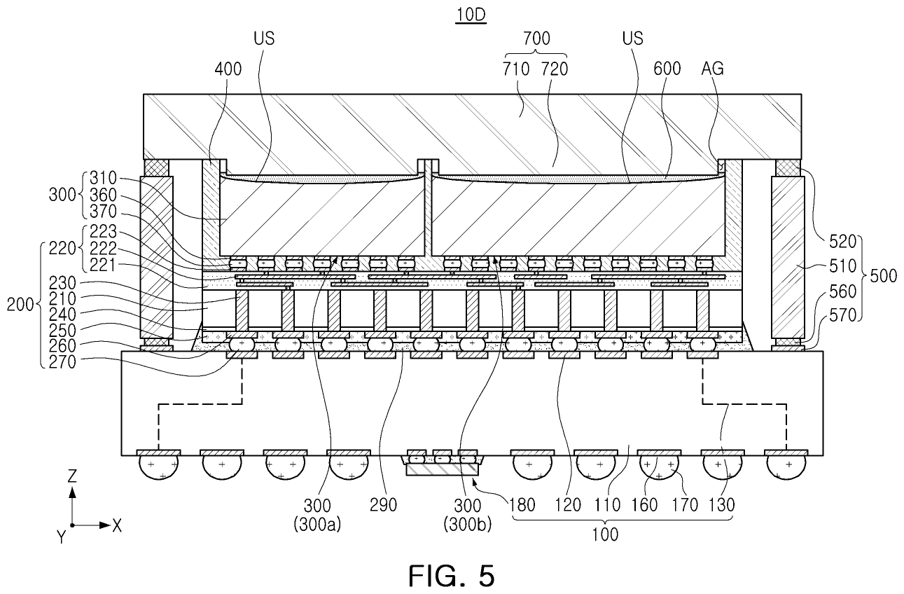

FIGS. 5 to 10 may be schematic cross-sectional views illustrating semiconductor packages according to example embodiments.

Referring to FIG. 5, unlike the semiconductor package 10C of FIGS. 4A and 4B, a semiconductor package 10D may include a molded underfill (MUF) structure integrated with an encapsulant 400 without including a semiconductor chip underfill 390. Since the semiconductor package 10D has the MUF structure, the encapsulant 400 may be formed by penetrating even between relatively narrow semiconductor chips 300. As described above, even in the semiconductor package 10 of FIGS. 1A to 1C, an MUF structure not including a semiconductor chip underfill 390 may be applied.

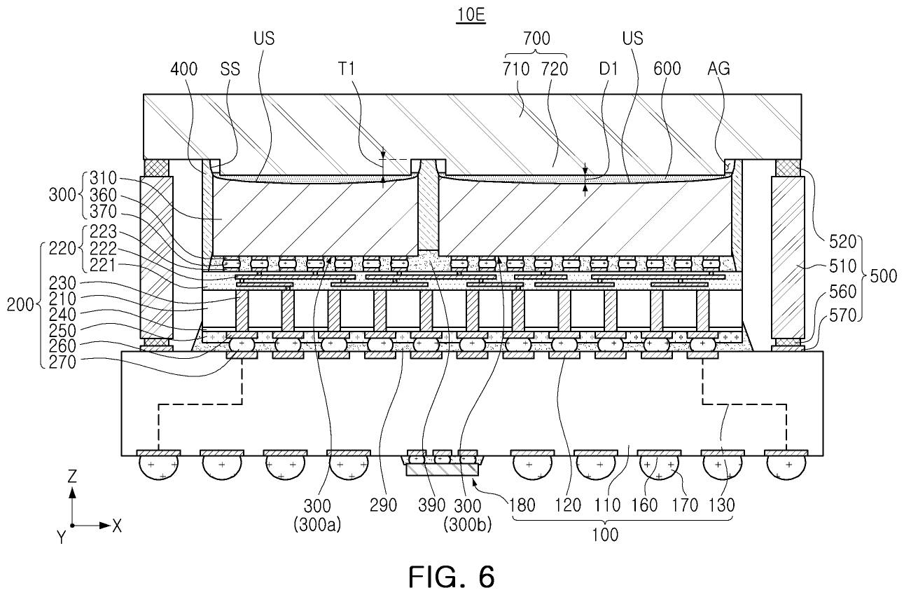

Referring to FIG. 6, unlike the semiconductor package 10 of FIGS. 1A to 1C, a semiconductor package 10E may include an encapsulant 400 having a recessed inner side surface SS. In a process of partially removing semiconductor chips 300 from an upper surface, a portion of the inner surface of the encapsulant 400 exposed on the upper surface of the semiconductor chips 300 may be etched together, and the encapsulant 400 may have the recessed inner side surface SS including an inclined portion closer to a side surface of a protrusion portion 720 facing the same as a level decreases. Inner side surfaces of the encapsulant 400 of the semiconductor package 10E, facing the side surface of the protrusion portion 720, may all be recessed inner side surfaces SS, but according to an embodiment, some of the encapsulant 400 may include an unetched portion together, like the semiconductor package 10 of FIGS. 1A to 1C.

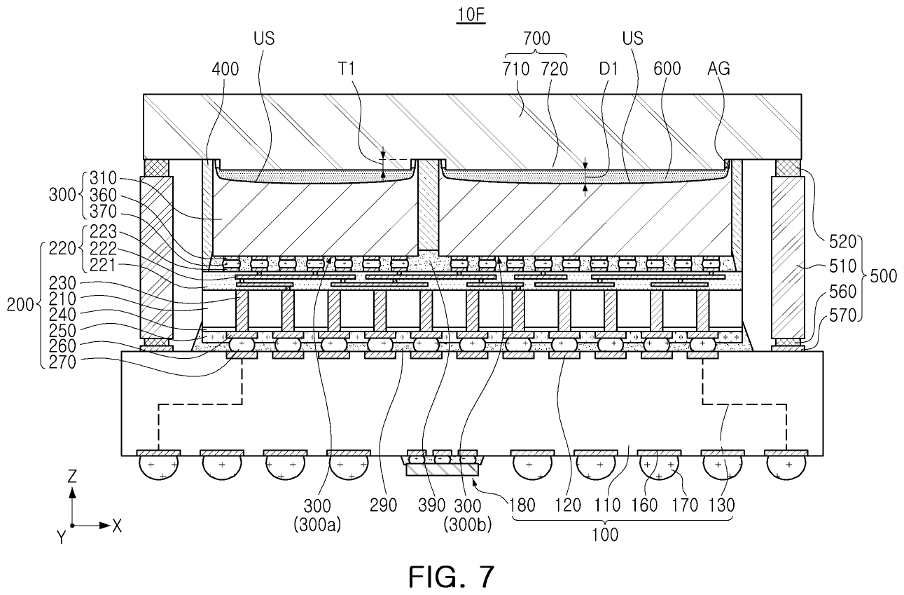

Referring to FIG. 7, unlike the semiconductor package 10 of FIGS. 1A to 1C, edges of recessed upper surfaces US of semiconductor chips 300 of a semiconductor package 10F may remain unetched. Upper ends of the semiconductor chips 300 may be located at the same level as an upper surface of an encapsulant 400. A side surface of a protrusion portion 720 may face the recessed upper surfaces US of the semiconductor chips 300. The encapsulant 400 may be spaced apart from a heat transfer material layer 600 by the recessed upper surfaces US of the semiconductor chips 300. An edge of a recessed upper surface US may be in contact with a lower surface of a plate portion 710 of a heat dissipation plate 700. In an embodiment, when the heat dissipation plate 700 is disposed to be spaced apart from the encapsulant 400, such as the semiconductor package 10B of FIG. 3, the edge of the recessed upper surface US may be spaced apart from the heat dissipation plate 700. The edge of the recessed upper surface US of the semiconductor chip 300 may be closer to the lower surface of the plate portion 710 of the heat dissipation plate 700 than to a central portion of the recessed upper surface US of the semiconductor chip 300. The edge of the upper surface of the semiconductor chip 300 may be located closer to the lower surface of the plate portion 710 of the heat dissipation plate 700 than the central portion of the upper surface of the semiconductor chip 300. According to an embodiment, the semiconductor package 10D may also include a portion in which the edges of the recessed upper surfaces US of the semiconductor chips 300 are located on a lower level than the upper surface of the encapsulant 400, like the semiconductor package 10 of FIGS. 1A to 1C.

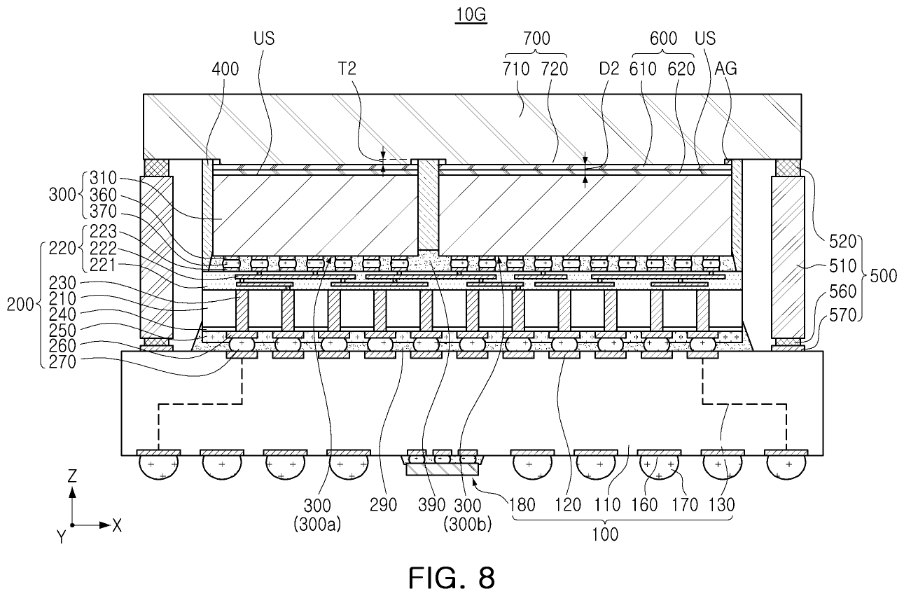

Referring to FIG. 8, unlike the semiconductor package 10 of FIGS. 1A to 1C, a recessed upper surface US of a semiconductor package 10G may be planar. The recessed upper surface US of the semiconductor package 10G may be formed by an anisotropic etching process, for example, a dry etching process. In an embodiment, a thickness D2 of a heat transfer material layer 600 may be 1 μm or less. Each of heat transfer material layers 600 may include a seed layer 620 contacting upper surfaces of semiconductor chips 300, and a heat dissipation layer 610 contacting a lower surface of a protrusion portion 720 of a heat dissipation plate 700 on the seed layer 620. In an embodiment, the seed layer 620 may include a material necessary for forming the heat dissipation layer 610 or facilitating fixation of the heat dissipation layer 610. For example, the seed layer 620 may include silicon nitride or titanium (Ti). The heat dissipation layer 610 may include, for example, at least one of aluminum (Al), gold (Au), silver (Ag), copper (Cu), iron (Fe), titanium (Ti), or nickel (Ni). Within a compatible range, the semiconductor package 10G of FIG. 8 may have characteristics of the semiconductor packages 10, 10A, 10B, 10C, 10D, 10E, and 10F of FIGS. 1A to 7. For example, an encapsulant 400 of the semiconductor package 10G may include a recessed inner surface SS, like the semiconductor package 10E of FIG. 6, or may have a structure in which upper ends of recessed upper surfaces US of the semiconductor chips 300 are located at the same level as upper surfaces of the encapsulant 400, like the semiconductor package 10F of FIG. 7. In an embodiment, the recessed upper surfaces US of the semiconductor chips 300 may be in contact with a lower surface of a plate portion 710 of the heat dissipation plate 700.

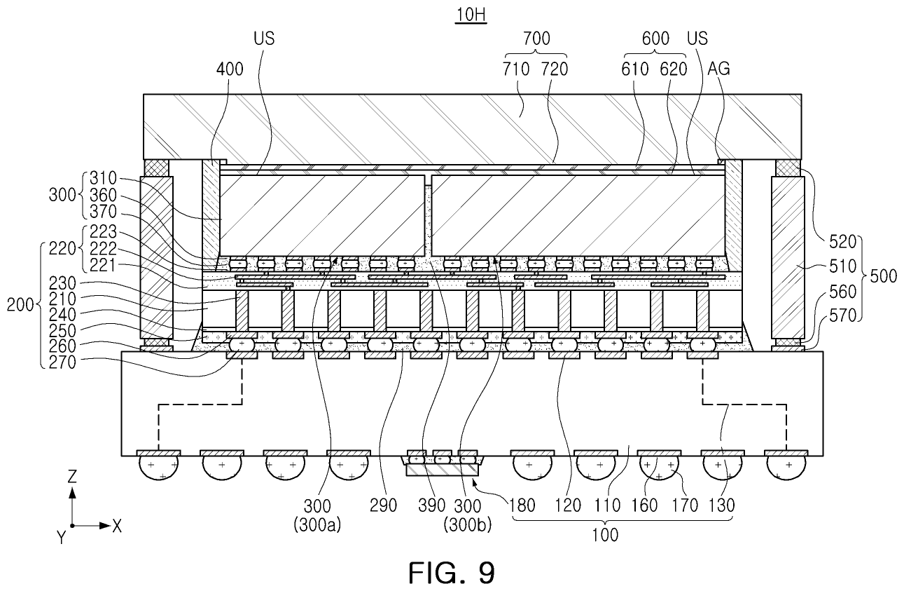

Referring to FIG. 9, unlike the semiconductor package 10G of FIG. 8, a semiconductor package 10H may include a heat dissipation plate 700 including a single protrusion portion 720. A gap between semiconductor chips 300 may be narrow enough that an encapsulant 400 does not penetrate, and a semiconductor chip underfill 390 may extend between the semiconductor chips 300 toward the heat dissipation plate 700. An upper end of the semiconductor chip underfill 390 may be located between the semiconductor chips 300, and may be in contact with a lower end of a heat transfer material layer 600, i.e., a lower end of a seed layer 620, on a level lower than upper surfaces of the semiconductor chips 300. The heat transfer material layer 600 may include a portion extending between the semiconductor chips 300 toward an interposer substrate 200, and the lower end of the heat transfer material layer 600 may be located between the semiconductor chips 300. Similar to the semiconductor package 10C of FIG. 3, the semiconductor package 10H may include a molded underfill (MUF) structure integrated with an encapsulant 400 without including an underfill 390. Within a compatible range, the semiconductor package 10H of FIG. 9 may have characteristics of the semiconductor packages 10, 10A, 10B, 10C, 10D, 10E, 10F, and 10G of FIGS. 1A to 8.

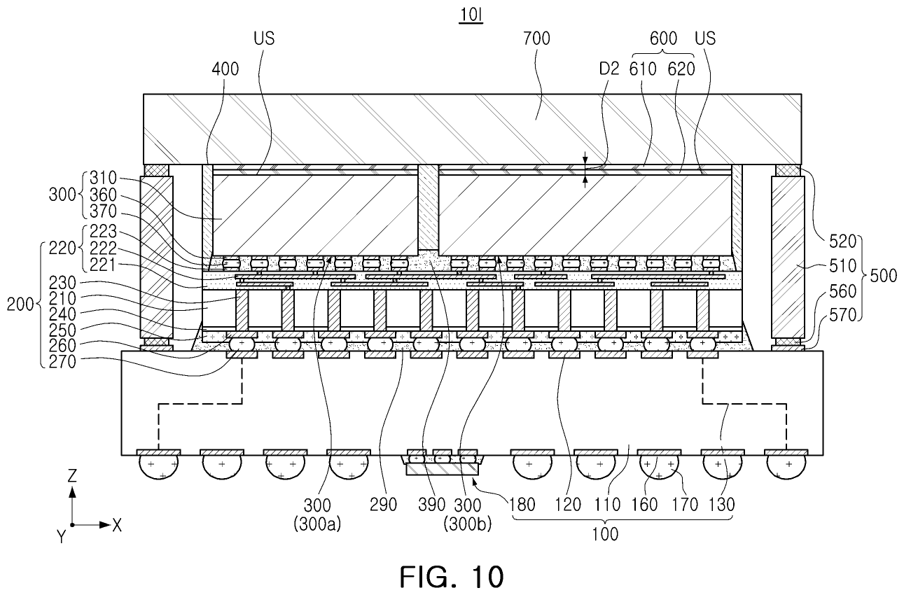

Referring to FIG. 10, unlike other semiconductor package embodiments, a heat dissipation plate 700 of a semiconductor package 10I may not include a protrusion portion 720. When a heat transfer material layer 600 is formed by a method of depositing metal or the like, the thickness of the heat transfer material layer 600 may be formed to be several μm or less, and the heat dissipation plate 700 may have a planar lower surface without a step difference. In the present embodiment, the heat dissipation plate 700 may be in contact with the heat transfer material layer 600 to receive and release heat generated from a semiconductor chips 300 through the heat transfer material layer 600.

As described above, the semiconductor packages of FIGS. 1A to 10 may be example embodiments, and respective characteristics thereof may be combined in various manners within a compatible range.

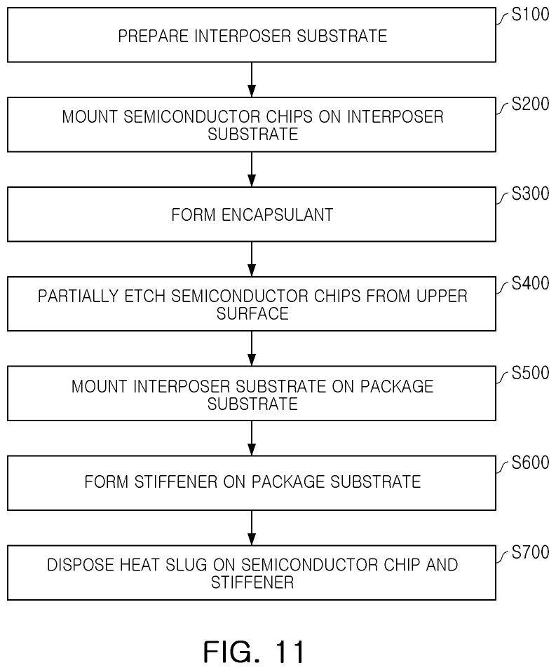

FIG. 11 is a schematic process flow diagram illustrating a method of manufacturing a semiconductor package according to example embodiments.

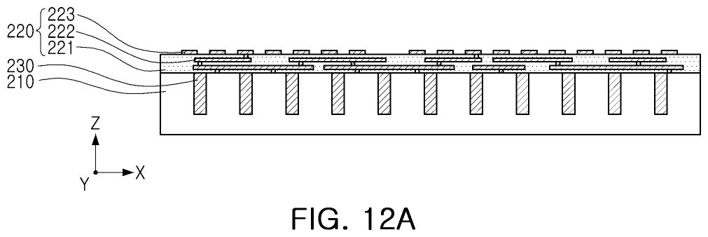

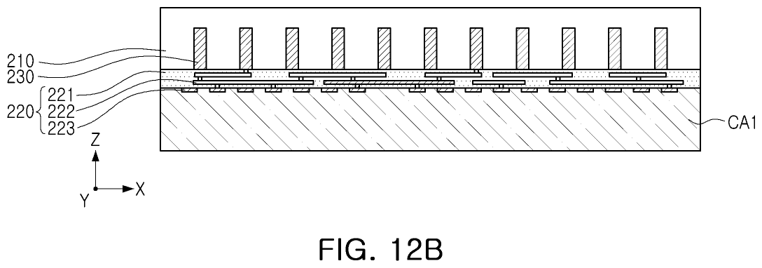

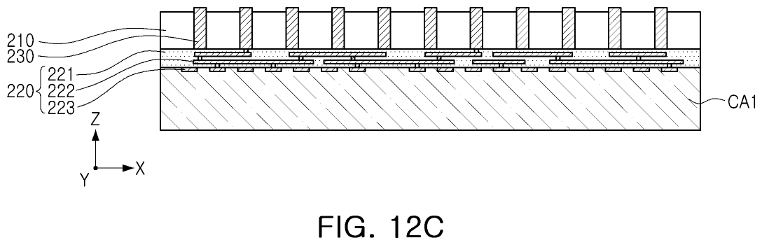

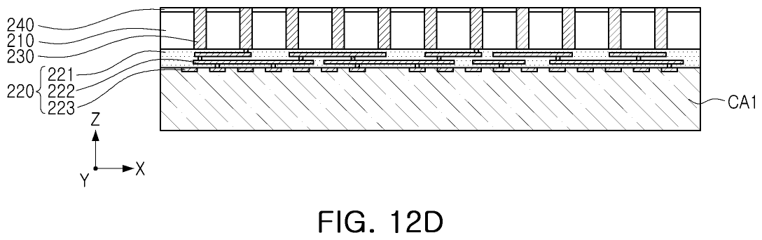

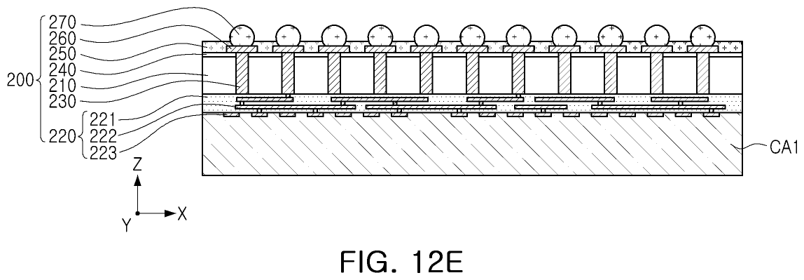

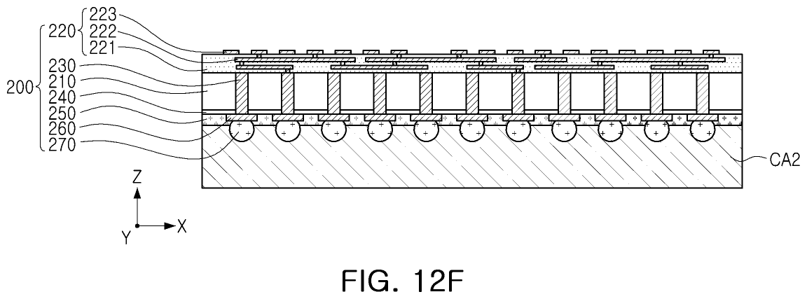

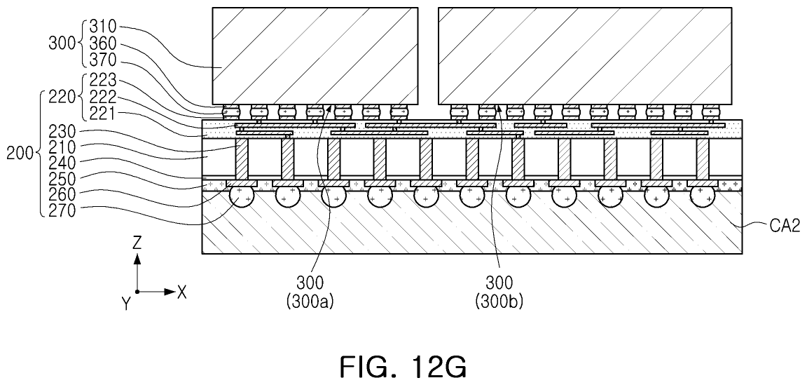

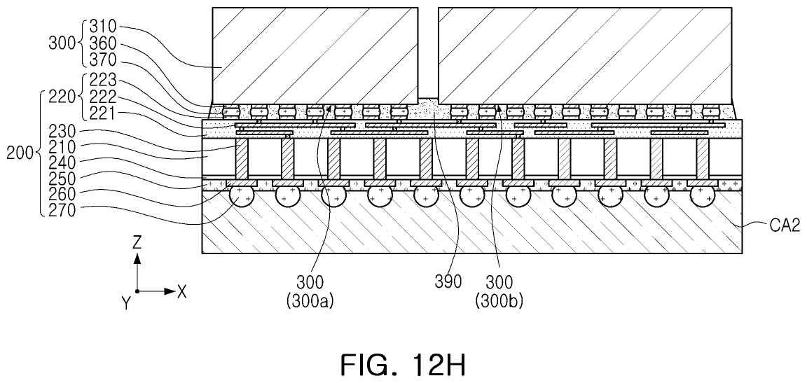

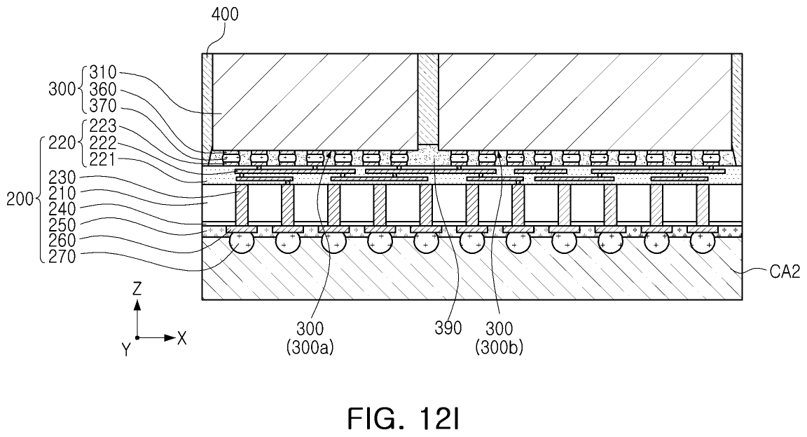

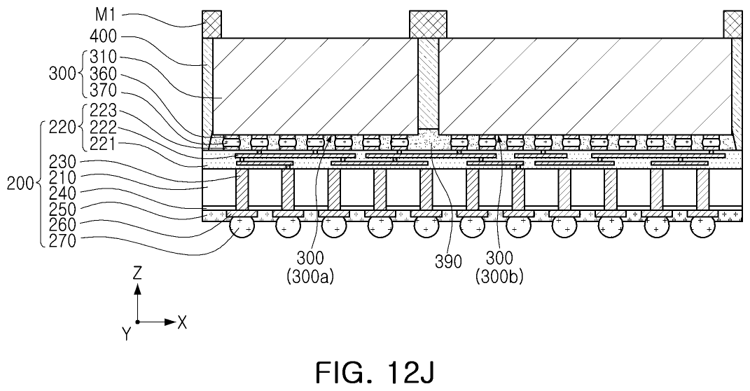

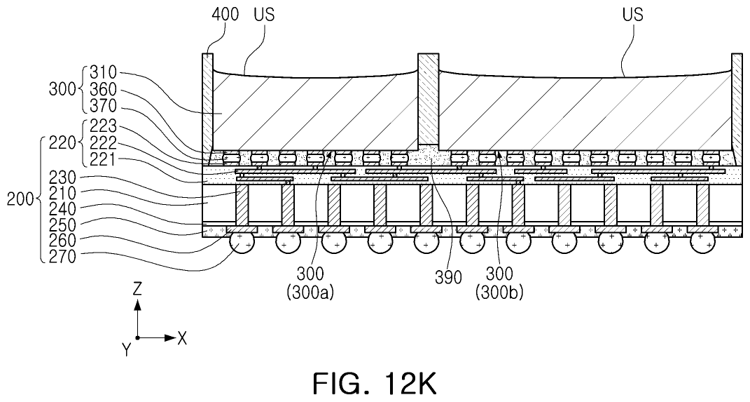

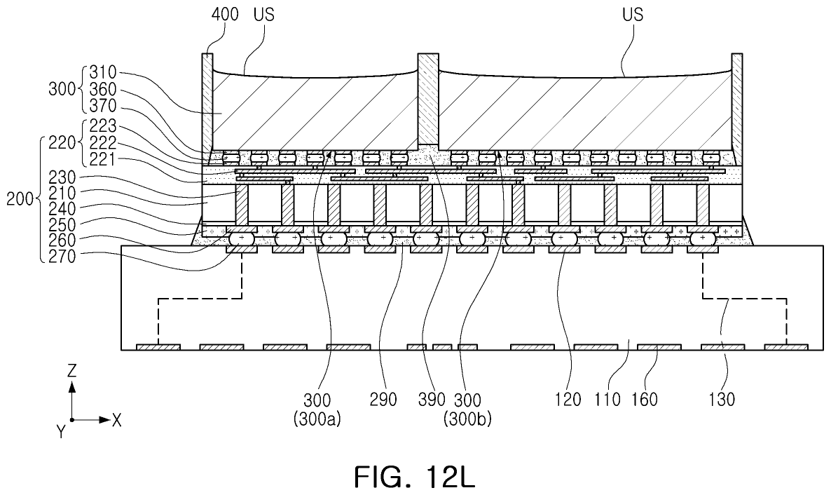

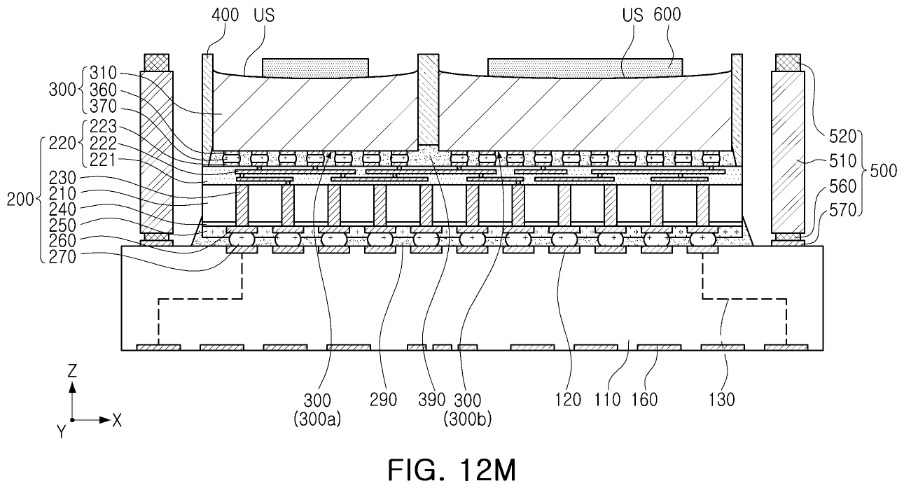

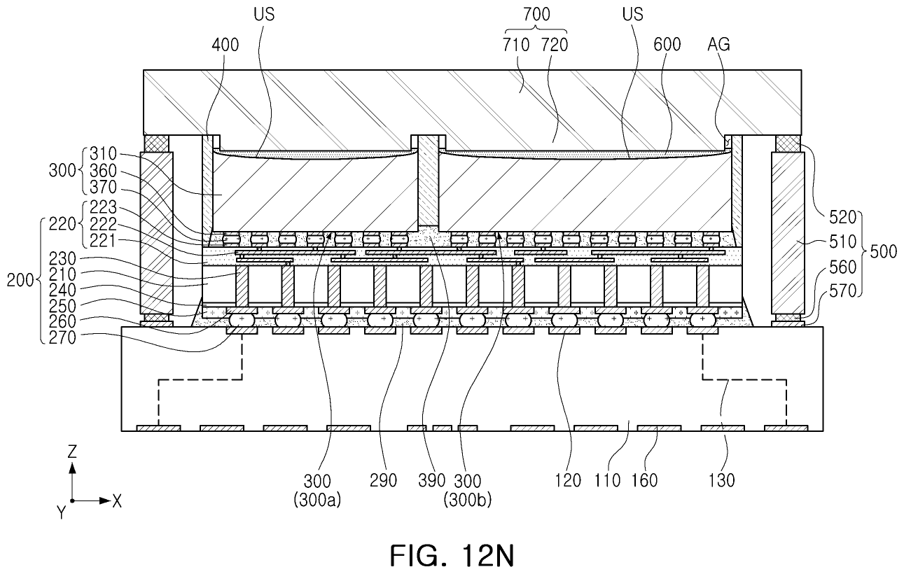

FIGS. 12A to 12N are cross-sectional views illustrating a process sequence to illustrate a method of manufacturing a semiconductor package according to example embodiments. FIGS. 12A to 12N illustrate areas corresponding to FIG. 1A, and illustrate a method for manufacturing the semiconductor package 10 of FIG. 1A.

FIGS. 12A to 12E may be included in S100 of preparing the interposer substrate 200 of FIG. 11.

Referring to FIG. 12A, a circuit layer 220 may be formed on a semiconductor substrate 210 and a through-via 230.

The semiconductor substrate 210 may cover a side surface and a lower surface of the through-via 230, and an upper surface of the through-via 230 may not be covered by the semiconductor substrate 210. The circuit layer 220 may be formed on the semiconductor substrate 210. An interlayer insulating layer 221 may be formed by applying and curing a photosensitive material, for example, a PID. An exposure process and a development process may be performed on the interlayer insulating layer 221 to form a connection circuit 222 and upper connection pads 223. The connection circuit 222 may be formed by forming a via hole penetrating the interlayer insulating layer 221 and patterning a metal material on the interlayer insulating layer 221 using a plating process. The connection circuit 222 may be formed by repeating an application process, a development process, and a plating process of the interlayer insulating layer 221.

Referring to FIG. 12B, the circuit layer 220 and the semiconductor substrate 210 may be disposed on a first carrier CA1.

In the first carrier CA1, for example, a polymer layer including a curable resin, and a metal layer including nickel (Ni), titanium (Ti), or the like, may be sequentially coated on a copper clad laminate (CCL). For a process on an upper surface (based on FIG. 9B) of the semiconductor substrate 210, the first carrier CA1 may be attached to a lower surface (based on FIG. 9B) of the circuit layer 220. The upper connection pads 223 may be embedded in a bonding layer that may be disposed on an upper surface of the first carrier CA1.

Referring to FIG. 12C, the semiconductor substrate 210 may be partially removed from an upper surface to partially expose the through-vias 230.

A portion of a side surface of the through-vias 230 may be exposed, as the semiconductor substrate 210 is partially removed from the upper surface. The semiconductor substrate 210 may be removed by a chemical mechanical polishing (CMP) process, an etch-back process, or a combination thereof.

Referring to FIG. 12D, a lower insulating layer 240 surrounding side surfaces of the through-vias 230 may be formed on the semiconductor substrate 210.

The lower insulating layer 240 may be formed by depositing and etching an insulating material on the semiconductor substrate 210. The lower insulating layer 240 may surround the side surfaces of the through-vias 230, and upper surfaces of the through-vias 230 may be exposed without being covered by the lower insulating layer 240.

Referring to FIG. 12E, a lower protective layer 250, lower connection pads 260, and connection conductors 270 may be formed on the lower insulating layer 240 to form an interposer substrate 200 (S100).

The lower connection pads 260 may be formed to cover the upper surface of the through-vias 230. The lower protective layer 250 may be formed to cover an upper surface of the lower protective layer 250 and side surfaces of the lower connection pads 260. The lower protective layer 250 may cover a portion of each of the lower connection pads 260, and may include an opening exposing a remaining portion. The connection conductors 270 may be formed on upper surfaces of the lower connection pads 260 exposed by the opening of the lower protective layer 250.

Referring to FIG. 12F, the interposer substrate 200 may be disposed on a second carrier CA2.

To perform a process on an upper surface of the interposer substrate 200, the interposer substrate 200 may be attached to the second carrier CA2 such that the lower protective layer 250 and the connection conductors 270 may be located therebelow, and the first carrier CA1 of FIG. 12E may be removed. In the second carrier CA2, for example, a polymer layer including a curable resin, and a metal layer including nickel (Ni), titanium (Ti), or the like, may be sequentially coated on a copper clad laminate (CCL). The connection conductors 270 may be embedded in the bonding layer that may be disposed on an upper surface of the second carrier CA2.

Referring to FIGS. 11 and 12G, semiconductor chips 300 may be mounted on the interposer substrate 200 (S200).

The semiconductor chips 300 may be mounted on the upper connection pads 223 of the interposer substrate 200. The semiconductor chips 300 may be mounted in a flip-chip manner. For example, the semiconductor chips 300 may be electrically connected to the upper connection pads 223 through a chip pad 360 and a chip bump 370.

FIGS. 12H to 12I may correspond to S300 of forming the encapsulant of FIG. 8.

Referring to FIG. 12H, a semiconductor chip underfill 390 may be formed.

The semiconductor chip underfill 390 may be formed between the semiconductor chips 300 and the interposer substrate 200. The semiconductor chip underfill 390 may be formed using a CUF process, but is not limited thereto. In an embodiment, an encapsulant 400 may be formed without separately forming the semiconductor chip underfill 390 through an MUF process.

Referring to FIG. 12I, an encapsulant 400 may be formed.

The encapsulant 400 may be formed to encapsulate at least a portion of each of the semiconductor chips 300 and the semiconductor chip underfill 390 on the interposer substrate 200. The encapsulant 400 may be formed, for example, by applying and curing EMC. A planarization process may be applied to an upper portion of the encapsulant 400. The planarization process may include a grinding process, a chemical mechanical polishing (CMP) process, or the like. The upper surfaces of the semiconductor chips 300 may be exposed to an upper surface of the encapsulant 400 by the planarization process.

FIGS. 12J to 12K may include S400 of partially etching the semiconductor chips 300 of FIG. 11 from the upper surface.

Referring to FIG. 12J, the second carrier CA2 may be removed, and a first mask M1 may be formed.

After the encapsulant 400 is formed, the second carrier CA2 may be removed. Thereafter, to etch upper surfaces of the semiconductor chips 300, the first mask M1 may be formed on the encapsulant 400. The first mask M1 may cover at least a portion of an upper surface of the encapsulant 400. The first mask M1 may cover a portion of edges of the upper surfaces of the semiconductor chips 300. In an embodiment, the first mask M1 may be a mask for performing an isotropic etching process. For example, the first mask M1 may be a mask for performing an isotropic etching process, and may include a metal. Depending on a width, a position, or the like. of the first mask M1, during a subsequent etching process, the encapsulant 400 may be partially etched together such that the encapsulant 400 may have a recessed side surface SS, like the semiconductor package 10E of FIG. 6, or edges of recessed upper surfaces US of the semiconductor chips 300 may partially remain, such that a structure, like the semiconductor package 10F of FIG. 7, is manufactured.

Referring to FIG. 12K, the first mask M1 may be used as an etching mask to partially remove the semiconductor chips 300 from the upper surface.

In an embodiment, the upper surfaces of the semiconductor chips 300 may be partially removed by a wet etching process. The wet etching process may be performed using a solution having etching selectivity with respect to silicon (Si) that the semiconductor chips 300 may include, and epoxy that the encapsulant 400 may include. By an isotropic etching process, the recessed upper surfaces US of the semiconductor chips 300 may be formed in a concave shape. Since the encapsulant 400 may be etching selectivity with respect to the semiconductor chips 300, the encapsulant 400 may not be etched. In an embodiment, when a portion of an inner side surface of the encapsulant 400 is etched together, the semiconductor package 10C of FIG. 4 may be manufactured by a subsequent process. In an embodiment, when a portion of upper surface edges of the semiconductor chips 300 is not etched, the semiconductor package 10D of FIG. 5 may be manufactured by a subsequent process. A final shape of the recessed upper surface US of the semiconductor chips 300, whether the encapsulant 400 is etched, or the like, may be variously modified by a width of the first mask M1, a type of etching solution used, an etching time, or the like.

Referring to FIGS. 11 and 12l, the interposer substrate 200 may be mounted on a package substrate 100 (S500), and an interposer underfill 290 may be formed.

The interposer substrate 200 may be mounted on upper pads 120 of the package substrate 100. The interposer underfill 290 may be formed between the semiconductor chips 300 and the interposer substrate 200. The interposer underfill 290 may be formed using a CUF process, but is not limited thereto.

Referring to FIG. 11 and FIG. 12M, a stiffener 500 may be formed (S600), and a heat transfer material layer 600 may be disposed on the semiconductor chip 300. The stiffener 500 may be formed by forming a support pad 570 and a lower bonding layer 560 on the package substrate, fixing a support structure 510 on the lower bonding layer 560, and forming an upper bonding layer 520 on the support structure 510. An upper surface of the upper bonding layer 520 may be formed to be located at the same level as the upper surface of the encapsulant 400. In an embodiment, the upper surface of the upper bonding layer 520 may be formed to be located on a higher level than the upper surface of the encapsulant 400, in which case, a structure in which the encapsulant 400 and a heat dissipation plate 700 are spaced apart, such as the semiconductor package 10B of FIG. 3, may be formed.

Referring to FIGS. 11 and 12N, the heat dissipation plate 700 may be disposed (S700).

In the heat dissipation plate 700, a lower surface of a plate portion 710 may be in contact with the upper surface of the encapsulant 400 and an upper surface of the stiffener 500, and a lower surface of a protrusion portion 720 may press the heat transfer material layer 600 on the recessed upper surface US of the semiconductor chips 300. The heat transfer material layer 600 may be spread to cover at least a portion of the recessed upper surface US of the semiconductor chips 300 by being pressed by the protrusion portions 720, and may be contact with an inner side surface of the encapsulant 400. Since the heat transfer material layer 600 may be located on a level lower than the upper surface of the encapsulant 400, it may be controlled not to leak out of an outer side surface of the encapsulant 400 during formation of the heat dissipation plate 700, and a semiconductor package having improved reliability may be provided. Thereafter, referring to FIG. 1A together, external connection terminals 170 and passive elements 180 may be formed on the lower pads 160 of the package substrate 100, and the semiconductor package 10 may be manufactured. By forming the recessed upper surface US by a wet etching process and forming the heat transfer material layer 600, a thickness of the heat transfer material layer 600 may be precisely controlled in a range of several tens μm to several hundreds of μm, for example, 30 μm to 150 μm. The heat transfer material layer 600 may be utilized to include a material that may be freely deformed, such as a polymer or the like.

In the following description of a manufacturing method, descriptions overlapping those referring to FIGS. 9A to 9N will be omitted.

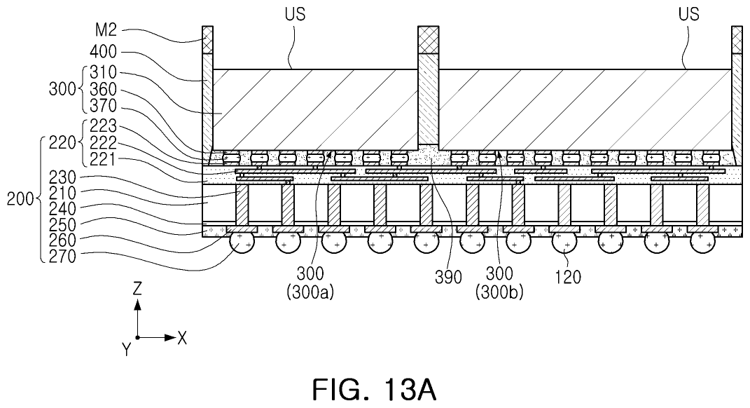

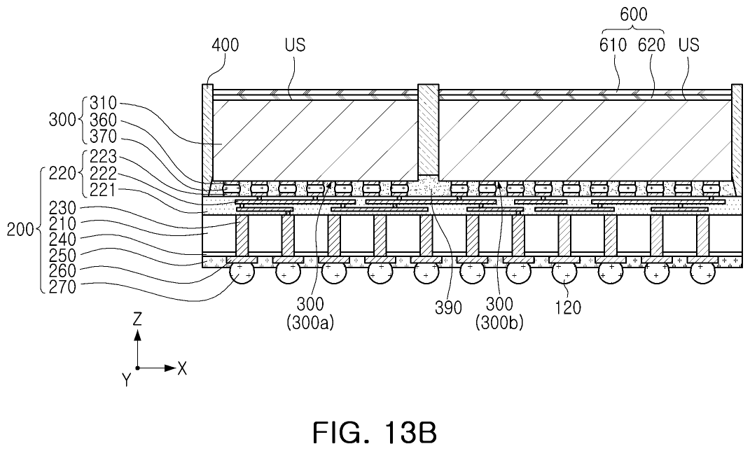

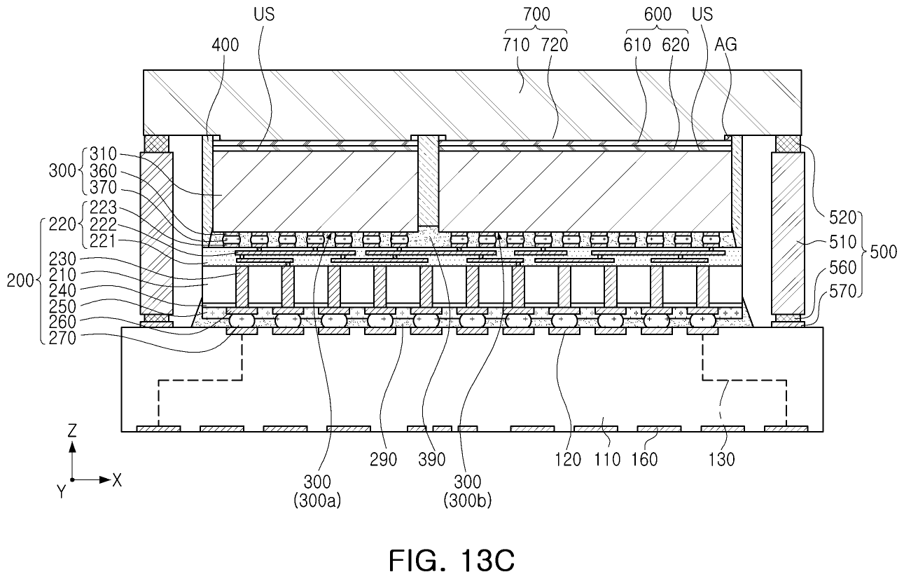

FIGS. 13A to 13C are cross-sectional views illustrating a method of manufacturing a semiconductor package according to example embodiments according to a process sequence. FIGS. 13A to 13C illustrate areas corresponding to FIG. 8. FIG. 13A may be an operation corresponding to FIG. 12K, FIG. 13B may be an operation corresponding to FIG. 12M, and FIG. 13C may be an operation corresponding to FIG. 12M. FIGS. 13A to 13C illustrate a method for manufacturing the semiconductor package 10E of FIG. 8.

Referring to FIG. 13A, unlike the process of FIG. 12K, a recessed upper surface US may be formed by partially removing semiconductor chips 300 from an upper surface using an anisotropic etching process. The recessed upper surface US may be formed to be planar. The anisotropic etching process may be performed by, for example, a dry etching process using plasma. Compared to a wet etching process, an amount to be etched may be precisely controlled. A second mask M2 may be a hard mask for the anisotropic etching process, and may include a photoresist or a dielectric. Unlike the process of FIG. 12K, the second mask M2 may be formed not to cover the upper surface of the semiconductor chips 300 or to cover relatively little the same. Similar to the process of FIG. 9K, depending on a width of the second mask M2, an etching material, a time, or the like, a portion of an inner side surface of an encapsulant 400 may be etched together, or an edge of the upper surface of the semiconductor chips 300 may not be etched. After the recessed upper surface US is formed, a wafer may be cut into package units to perform a subsequent process.

Referring to FIG. 13B, a heat transfer material layer 600 may be formed.

The heat transfer material layer 600 may be formed by forming a seed layer 620 on the recessed upper surface US, and forming a heat dissipation layer 610 on the seed layer 620. In an embodiment, the seed layer 620 may be formed by depositing silicon oxide or depositing a metal material such as titanium (Ti) or the like. In an embodiment, the heat dissipation layer 610 may be formed by depositing or plating a conductive material or the like on the seed layer 620 depending on a material included. In an embodiment, the heat transfer material layer 600 may be formed by disposing not only a polymer but also a metal sheet. By etching the upper surface of the semiconductor chips 300 by a dry etching method and forming the heat transfer material layer 600, a thickness of the heat transfer material layer 600 may be controlled within a range of several μm or less, or precisely controlled within a nm unit of 1 μm or less.

Referring to FIG. 13C, an interposer substrate 200 may be mounted on a package substrate 100, and subsequent processes such as forming a stiffener 500 and a heat dissipation plate 700 may be performed. Referring to FIG. 8 together, the semiconductor package 10G of FIG. 8 may be manufactured by forming external connection terminals 170 and passive elements 180 on lower pads 160.

According to embodiments, a semiconductor package having improved reliability and a method for manufacturing the same may be provided by selectively etching an upper surface of a semiconductor chip to form a trench structure and forming a heat transfer material layer and a heat slug on the semiconductor chip.

Various advantages and effects of the present inventive concept are not limited to the above-described contents, and will be more easily understood in the process of explaining specific embodiments.

While example embodiments have been illustrated and described above, it will be apparent to those skilled in the art that modifications and variations could be made without departing from the scope of the present inventive concept as defined by the appended claims.

What is claimed is:

1. A semiconductor package comprising:
a package substrate;
an interposer substrate disposed on the package substrate;
a semiconductor chip disposed on the interposer substrate and electrically connected to the package substrate;
a heat transfer material layer disposed on the semiconductor chip;
an encapsulant surrounding at least a portion of the semiconductor chip and at least a portion of the heat transfer material layer on the interposer substrate;
a stiffener disposed on the package substrate and spaced apart from the interposer substrate; and
a heat dissipation plate disposed on an upper end of the stiffener, an upper end of the encapsulant, and an upper end of the heat transfer material layer,
wherein the heat dissipation plate includes a plate portion located on a level higher than the upper end of the encapsulant, and a protrusion portion protruding from a lower surface of the plate portion toward the semiconductor chip,
the lower surface of the plate portion of the heat dissipation plate is in contact with the upper end of the stiffener,
the heat transfer material layer is in contact with an upper surface of the semiconductor chip and a lower surface of the protrusion portion of the heat dissipation plate, and
at least a portion of a side surface of the protrusion portion of the heat dissipation plate is spaced apart from the encapsulant.

2. The semiconductor package of claim 1, wherein the upper end of the encapsulant is located on a level higher than the upper surface of the semiconductor chip.

3. The semiconductor package of claim 1, wherein the upper surface of the semiconductor chip has a concave shape, and
a lower surface of the heat transfer material layer has a curved shape along the concave shape of the upper surface of the semiconductor chip.

4. The semiconductor package of claim 3, wherein an edge of the upper surface of the semiconductor chip is located on a level closer to the lower surface of the plate portion of the heat dissipation plate than a central portion of the upper surface of the semiconductor chip.

5. The semiconductor package of claim 1, wherein a lower end of the heat transfer material layer is located on a level lower than an upper end of the semiconductor chip.

6. The semiconductor package of claim 1, wherein the stiffener has a ring shape surrounding the interposer substrate on the package substrate.

7. The semiconductor package of claim 1, wherein the encapsulant includes an inner side surface facing the side surface of the protrusion portion of the heat dissipation plate, and
the inner side surface includes a portion inclined toward the protrusion portion of the heat dissipation plate, as a level decreases.

8. The semiconductor package of claim 1, wherein the heat transfer material layer includes a seed layer covering the upper surface of the semiconductor chip, and a heat dissipation layer disposed on the seed layer and contacting the lower surface of the protrusion portion of the heat dissipation plate.

9. The semiconductor package of claim 8, wherein a protrusion length of the protrusion portion of the heat dissipation plate is 1 μm or less.

10. The semiconductor package of claim 8, wherein the seed layer includes silicon nitride, and
the heat dissipation layer includes at least one of aluminum (Al), gold (Au), silver (Ag), copper (Cu), iron (Fe), titanium (Ti), or nickel (Ni).

11. The semiconductor package of claim 1, wherein the encapsulant includes an inner side surface facing the side surface of the protrusion portion of the heat dissipation plate, and
the heat transfer material layer is in contact with the inner side surface of the encapsulant.

12. A semiconductor package comprising:
an interposer substrate;
a semiconductor chip disposed on the interposer substrate;
a heat transfer material layer covering at least a portion of an upper surface of the semiconductor chip;
an encapsulant surrounding a side surface of the semiconductor chip and a side surface of the heat transfer material layer on the interposer substrate;
a heat dissipation plate disposed on the encapsulant and including a protrusion portion protruding toward the semiconductor chip; and
an air gap disposed between a side surface of the protrusion portion and the encapsulant.

13. The semiconductor package of claim 12, wherein the air gap is an empty space confined by the heat dissipation plate, the encapsulant, and the heat transfer material layer.

14. The semiconductor package of claim 13, wherein the air gap surrounds the side surface of the protrusion portion.

15. The semiconductor package of claim 12, wherein a planar area of the heat dissipation plate is greater than a planar area of the interposer substrate.

16. The semiconductor package of claim 12, wherein a planar area of the protrusion portion is smaller than a planar area of the semiconductor chip.

17. A semiconductor package comprising:
a package substrate;
an interposer substrate disposed on the package substrate;
a stiffener disposed on the package substrate and located more adjacent to an edge of an upper surface of the package substrate than the interposer substrate;
a plurality of semiconductor chips including a first semiconductor chip and a second semiconductor chip, disposed on the interposer substrate and spaced apart from each other in a horizontal direction perpendicular to a stacking direction of the package substrate and the interposer substrate;
an encapsulant surrounding side surfaces of the plurality of semiconductor chips on the interposer substrate;
a heat dissipation plate disposed on an upper surface of the encapsulant and an upper surface of the stiffener; and
at least one heat transfer material layer disposed between the plurality of semiconductor chips and the heat dissipation plate,
wherein an upper surface of the heat transfer material layer is located on a level lower than the upper surface of the encapsulant,
a first portion which is a portion of the upper surface of the heat transfer material layer is in contact with the heat dissipation plate, and a second portion which is a remaining portion of the upper surface of the heat transfer material layer is spaced from the heat dissipation plate along the stacking direction, and
the second portion surrounds at least a portion of the first portion.

18. The semiconductor package of claim 17, wherein at least a portion of the second portion is located on a level higher than or equal to the first portion.

19. The semiconductor package of claim 17, further comprising an underfill disposed between the plurality of semiconductor chips and an upper surface of the interposer substrate, and
an upper end of the underfill is located between side surfaces of the first semiconductor chip and the second semiconductor chip facing each other.

20. The semiconductor package of claim 17, wherein a lower surface of the heat dissipation plate has a step difference in a portion in which the heat dissipation plate overlaps the plurality of semiconductor chips.
